(19) United States
(12) Patent Application Publication
(10) Pub. No.: US 2012/0119350 A1
(43) Pub. Date: May 17, 2012

(54) Heat Sink Module

(75) Inventor: Fu-Sheng LIANG, Taipei (TW)

(73) Assignee: Victory Industrial Corporation, Taipei (TW)

(21) Appl. No.: 13/189,682

(22) Filed: Jul. 25, 2011

(30) Foreign Application Priority Data
Nov. 11, 2010 (TW) 099221878

(51) Int. Cl. H01L 23/34

(52) U.S. Cl. 257/712; 257/E23.08

(57) ABSTRACT

An improved heat sink module includes a main body and at least one diode. Mounting brackets, each having a through hole, extend from the outer periphery of the arcuate main body. A plurality of engaging holes are formed on the backside of the main body and each have at least one vent slot. To increase the heat dissipation area and yield rate of the main body, a plurality of upright, alternately arranged first and second fins are provided on the front side of the main body. The first fins extend between the inner and the outer peripheries of the main body, whereas the second fins extend from the outer periphery toward the inner periphery but are spaced therefrom. Each diode is peripherally provided with engaging ribs and has a wired end. The vent slots allow the at least one diode to be inserted into the engaging holes without difficulty.

### CROSS REFERENCE TO RELATED APPLICATIONS

This application claims the benefit of priority of Application TW 099221878, entitled “Heat Sink Module,” filed Nov. 11, 2010, the contents of which are herein incorporated by reference for all purposes.

### BACKGROUND

The present invention relates to a heat sink module and, more particularly, to an improved heat sink module having a main body whose backside is provided with at least one diode and a plurality of engaging holes each formed with a vent slot, and whose front side is provided with a fin array composed of a plurality of alternately arranged first and second fins, wherein the first fins extend farther than the second fins.

FIGS. 1 to 3 shows a front side perspective view, a front side plan view, and a backside perspective view, respectively, of a conventional heat sink module for dissipating the heat generated by the rectifier diode(s) of an automotive alternator. As is well known in the art, the direct current used by a car is provided indirectly by an automotive alternator, whose working principle is briefly stated as follows. When the alternator is driven by a belt connected to the car engine, the magnetic field of the rotor revolves with respect to the wires in the alternator. As a result, an electromotive force is generated in the wires, and the direction of the electromotive force can be determined by Fleming's right hand rule, i.e., with the thumb indicating the direction of motion; the index finger, of the magnetic field; and the middle finger, of the induced current.

In order to convert the alternating current generated by the stator windings of the alternator into direct current for output, the alternator is provided with at least one diode 3 as a rectifier. If the diode 3 is configured for single-phase half-wave rectification, only one such diode 3 is needed. Alternatively, four single-phase full-wave rectifier diodes 3, or four three-phase half-wave rectifier diodes 3, or six three-phase full-wave rectifier diodes 3 can be used.

As shown in FIG. 3, the diodes 3 in the conventional heat sink module are fixed to the backside of a finned main body 100 by solder joints 30. However, the solder joints 30 require a time-consuming soldering process and are not necessarily neatly and securely formed on the main body 100. On the other hand, the diodes 3 are high-power silicon diodes and can be divided into positive diodes 3 and negative diodes 3, all of which have the same shape. A positive diode 3 is different from a negative diode 3 in that the p-type semiconductor and the n-type semiconductor in a positive diode 3 are in opposite positions to those in a negative diode 3; therefore, current runs in opposite directions in the two types of diodes 3 respectively, wherein resistance is low in the p-to-n direction, and high in the n-to-p direction.

Now that current is output from the alternator via the positive diodes 3, whose operating temperature must not exceed about 150° C., the main body 100 is typically provided with a plurality of fins 200 and a fan for lowering the temperature of the diodes 3. The provision of a plurality of fins 200 is intended to increase the area for heat dissipation. However, when the number of the fins 200 provided on the main body 100 (FIGS. 1 and 2) is augmented to increase the heat dissipation area, the fins 200 tend to connect with each other along the inner periphery of the main body 100. Should that happen, the gaps which are originally designed to enable air circulation between the fins 200 will be blocked at one end, thus raising the rate of defective or rejected products.

In order to prevent such structural defects, the fins 200 must be spaced farther apart from each other. Consequently, the fins 200 are only loosely arranged on the main body 100, as shown in FIGS. 1 and 2, and the heat dissipation area decreases with the number of the fins 200. If the heat dissipation effect of the heat sink module is seriously compromised, the diodes 3 are very likely to fail or even burn when subjected to high temperature for an extended period of time.

### SUMMARY

The present invention provides an improved heat sink module whose heat-dissipating fins, and hence the heat dissipation area, are effectively increased without the risk of having the inner ends of the fins connected to each other. Thus, the gaps for air circulation between the fins are prevented from blockage to ensure not only a high yield rate of the main body of the heat sink module, but also long services lives of the diodes in the heat sink module. Further exemplary, the diodes can be directly and smoothly press-fitted into and thereby connected with the main body so as to simplify the assembly process of the heat sink module.

Therefore, the primary object of the present invention is to provide a structurally improved heat sink module capable of overcoming the aforesaid drawbacks of the prior art.

To achieve the above object, the present invention provides an improved heat sink module which includes a main body and at least one diode.

The main body includes mounting brackets extending from the outer periphery of the main body, wherein each mounting bracket is formed with a through hole. Further exemplary, a plurality of engaging holes and an upright fin array are provided on the backside and the front side of the main body respectively. The fin array includes a plurality of alternately arranged first fins and second fins. Each first fin extends between the inner and the outer peripheries of the main body, whereas each second fin extends from the outer periphery of the main body toward the inner periphery but is spaced from the inner periphery.

The at least one diode is provided in the engaging holes of the main body. Each diode is peripherally provided with engaging ribs. Each diode also has one end connected with wires.

In one embodiment, the main body is arcuate. In other embodiments, the main body is shaped like a horseshoe, or has a semicircular shape.

Further exemplary, each engaging hole on the backside of the main body has an inner surface provided with at least one vent slot.

In a specific exemplary embodiment, the total number of the first and the second fins in the fin array ranges from 40 to 47.

The foregoing technical features not only allow the at least one diode to be inserted into and engaged with the main body without difficulty, but also increase the heat dissipation area, and simplify the manufacturing process, of the main body effectively.

### BRIEF DESCRIPTION OF THE DRAWINGS

The structure as well as a preferred mode of use, further objects, and advantages of the present invention will be best understood by referring to the following detailed description of an illustrative embodiment in conjunction with the accompanying drawings, in which:

FIG. 1 is a front side perspective view of a conventional heat sink module;

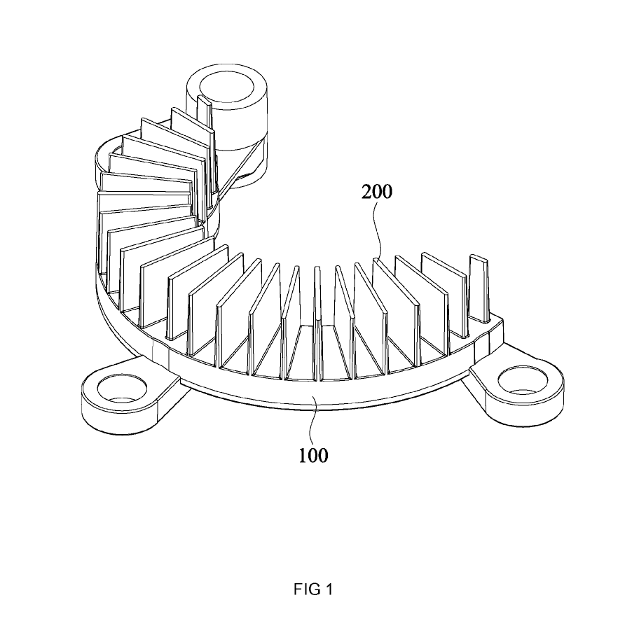

FIG. 2 is a front side plan view of the conventional heat sink module depicted in FIG. 1,

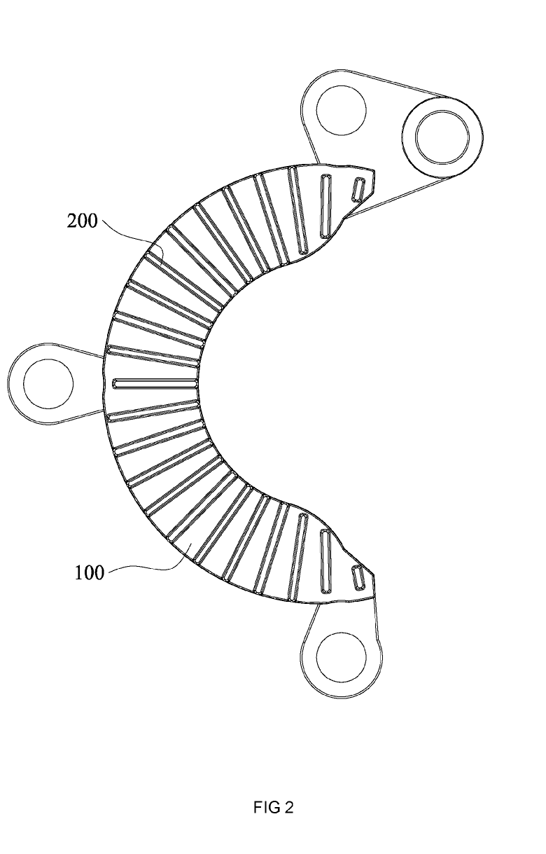

FIG. 3 is a backside perspective view of the conventional heat sink module depicted in FIG. 1;

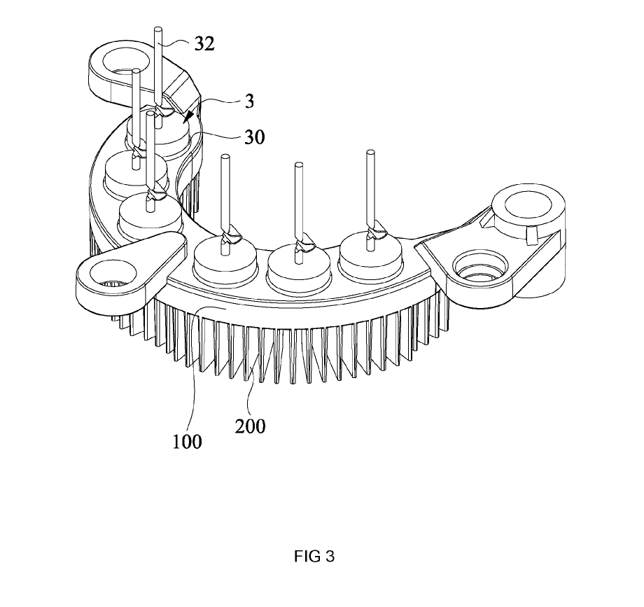

FIG. 4 is a front side perspective view of an exemplary heat sink module according to the present invention;

FIG. 5 is a front side plan view of the heat sink module depicted in FIG. 4;

FIG. 6 is an exploded perspective view of the heat sink module depicted in FIG. 4, showing in particular the backside of the heat sink module and a diode;

FIG. 7 is an assembled perspective view of the heat sink module depicted in FIG. 6;

FIG. 8 is a backside plan view of the heat sink module depicted in FIG. 6, with the diode in place; and

FIG. 9 is a sectional view taken along line A-A in FIG. 8.

### DETAILED DESCRIPTION OF EXEMPLARY EMBODIMENTS

The drawings are provided for illustrative and supplementary purposes only but are not intended to reflect the actual proportions and precise arrangement to be observed when implementing the present invention. Therefore, the proportions and arrangement shown in the drawings should not be construed as restrictive of the scope of the present invention.

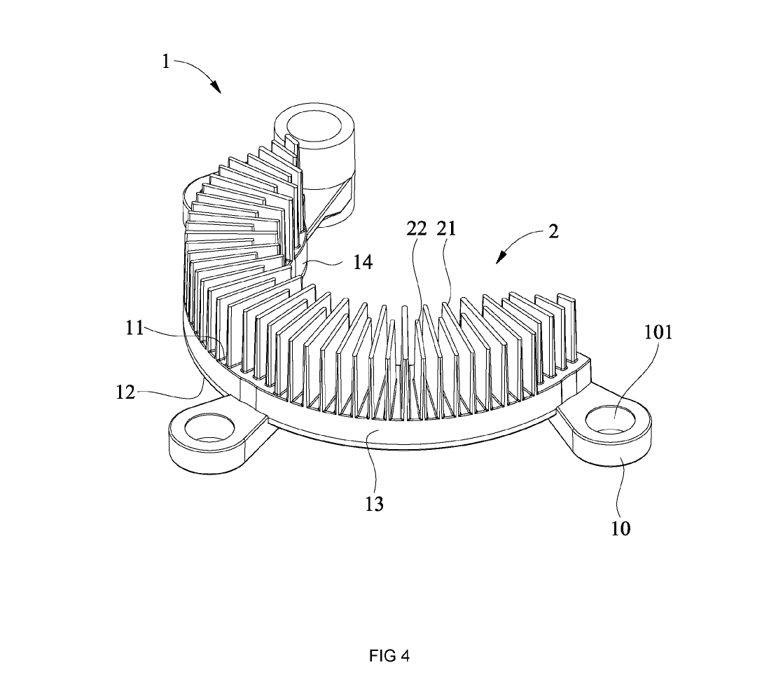

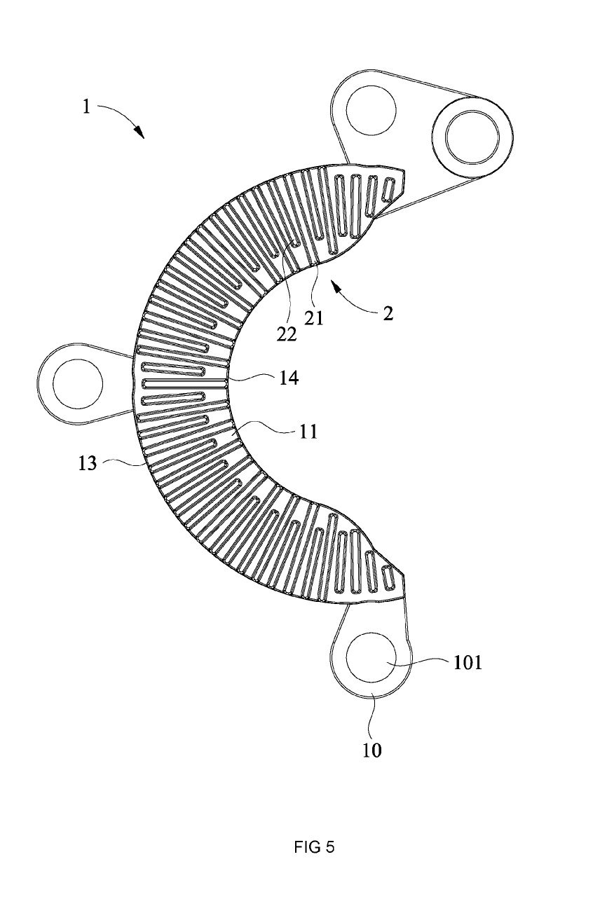

FIGS. 4 through 7 show a front side perspective view, a front side plan view, an exploded perspective view, and an assembled perspective view, respectively, of an improved heat sink module according to an exemplary embodiment of the present invention. As shown in the drawings, the heat sink module includes a main body 1 and at least one diode 3.

The main body 1 in this embodiment has an arcuate shape, although the main body 1 may be of any shape. For example, in alternative embodiments the main body 1 can be of a horseshoe shape, a semicircular shape, or any other shapes.

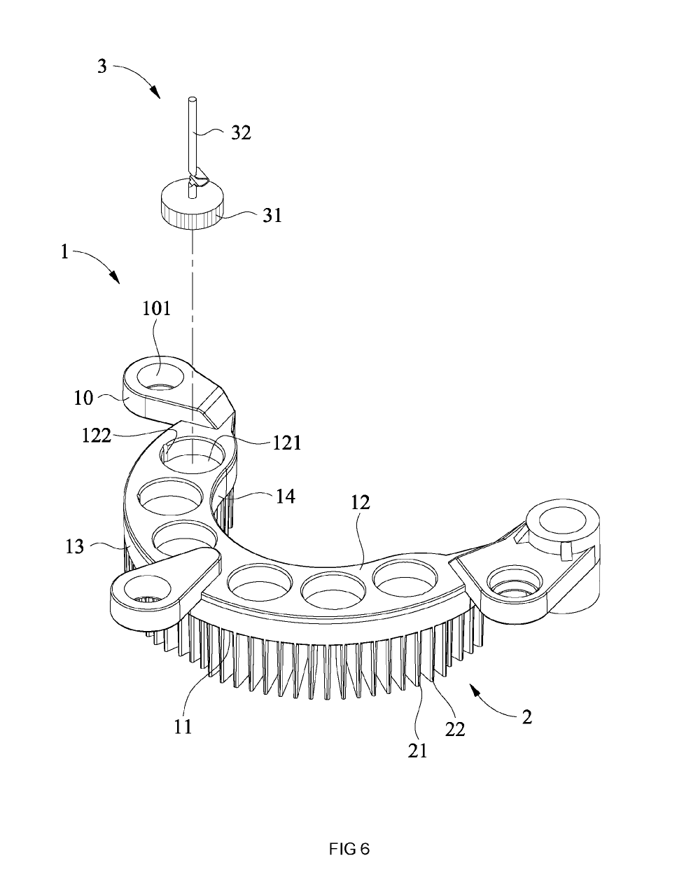

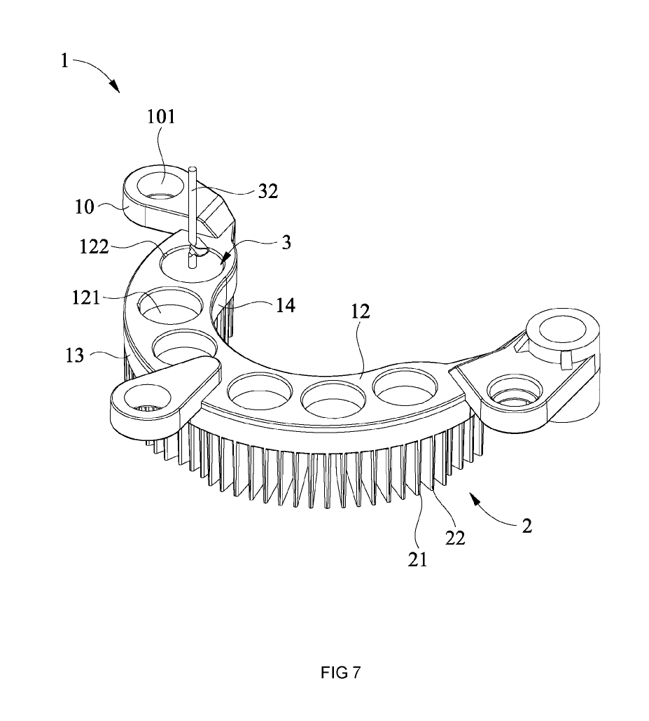

In order to be mounted on an alternator, the main body 1 is provided with mounting brackets 10 extending outward from the outer periphery of the main body 1, and each mounting bracket 10 has a through hole 101. In addition, a plurality of engaging holes 121 are concavely provided on the backside 12 of the main body 1. As can be seen more clearly in FIGS. 6 and 7, the inner surface of each engaging hole 121 is formed with at least one vent slot 122 which extends along the height of and communicates with the engaging hole 121.

The front side of the main body 1 is provided with an upstanding fin array 2, wherein the fin array 2 includes a plurality of first fins 21 and a plurality of second fins 22. The first and the second fins 21, 22 are arranged in an alternate manner. Each first fin 21 extends between the inner periphery 14 and the outer periphery 13 of the main body 1. Each second fin 22 extends from the outer periphery 13 of the main body 1 toward the inner periphery 14 but is spaced from the inner periphery 14. Thus, the first fins 21 (which extend between the inner and the outer peripheries 14, 13 of the main body 1) and the second fins 22 (which are spaced from the inner periphery 14 of the main body 1) not only alternate with each other but also form a zigzag pattern near the inner periphery 14 of the main body 1. Consequently, the first and the second fins 21, 22 are prevented from connecting with each other, and the gaps between the fins 21, 22 are kept open at both ends to facilitate air circulation.

Compared with the conventional heat sink module, the number and the heat dissipation area of the first and the second fins 21, 22 in the fin array 2 are increased, and the yield rate of the main body 1 is expected to be much higher. In a specific exemplary embodiment, the total number of the first and the second fins 21, 22 in the fin array 2 is preferably 40 to 47, but any number of fins in the fin array 2 may be implemented in alternative embodiments under the present invention.

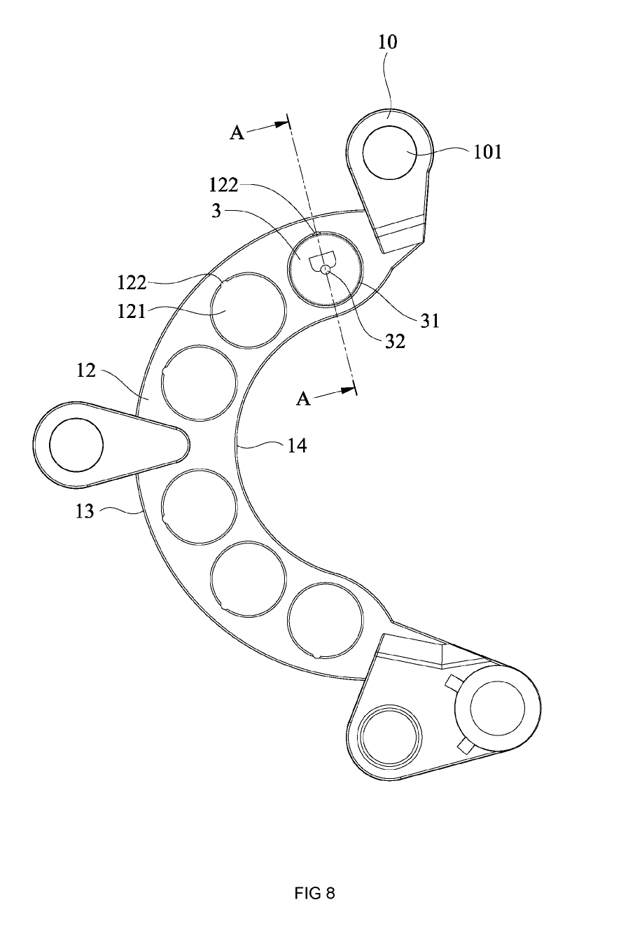

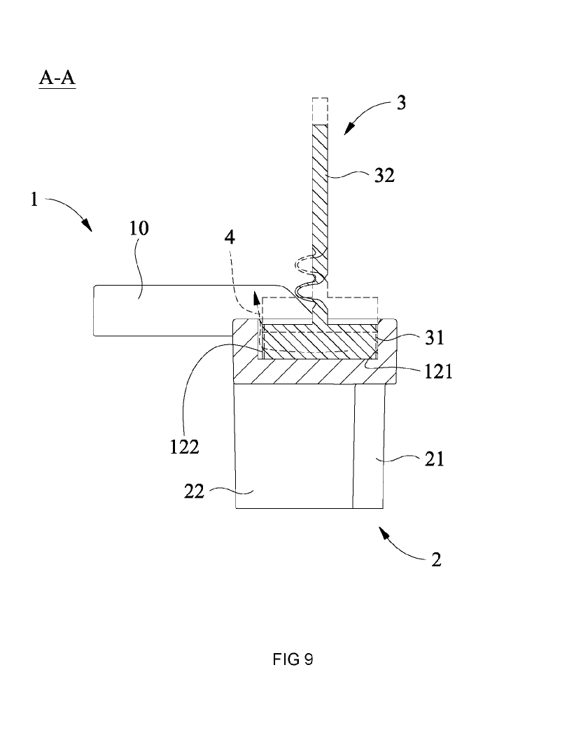

The at least one diode 3 is disposed in the engaging holes 121 on the backside 12 of the main body 1, and each diode 3 generally corresponds in shape to an individual engaging hole 121. In this embodiment, the engaging holes 121 are cylindrical, and so is the at least one diode 3. The shapes of the engaging holes 121 and the at least one diode 3 are not limited to that illustrated, and may be any corresponding shapes without departing from the scope of the present invention. Furthermore, in order to fit the at least one diode 3 securely in the engaging holes 121, each diode 3 is peripherally provided with a plurality of engaging ribs 31. The at least one diode 3 can be press-fitted firmly in the engaging holes 121 by engagement between the engaging ribs 31 and the engaging holes 121. Since each engaging hole 121 on the backside 12 of the main body 1 has at least one vent slot 122 on the inner surface and is in communication with the at least one vent slot 122, when a diode 3 is press-fitted into one of the engaging holes 121 of the main body 1, the air 4 otherwise sealed in the space below the diode 3 is discharged through the at least one vent slot 122 in the engaging hole 121 (FIGS. 8 and 9). Therefore, the at least one diode 3 can be inserted smoothly into and engaged with the main body 1 without difficulty. In addition, each diode 3 is provided with wires 32 at one end, and the wires 32 of each diode 3 are connected with the two ends of the corresponding stator windings in the alternator, so as for the at least one diode 3 to convert alternating current into direct current.

According to the design described above, the at least one diode 3 can be engaged with the main body 1 without difficulty, and the heat dissipation area of the main body 1 is effectively increased. Apart from that, the heat sink module disclosed herein features a high yield rate and high assembly efficiency.

The foregoing preferred embodiment is illustrative of the technical concepts and characteristics of the present invention, with a view to enabling a person skilled in the art to gain insight into the contents disclosed herein and implement the present invention accordingly. The disclosed embodiment, however, is not intended to restrict the scope of the present invention. Hence, all equivalent modifications and variations which are made to the disclosed embodiment and based on the principle of the present invention should fall within the scope of the appended claims.

What is claimed is:

1. A heat sink module, comprising:
a main body having an outer periphery provided with outwardly extending mounting brackets, wherein each said mounting bracket has a through hole, the main body further having a backside formed with a plurality of engaging holes and a front side provided with an upright fin array, the fin array comprising a plurality of alternately arranged first fins and second fins, wherein each said first fin extends between an inner periphery and the outer periphery of the main body, and each said second fin extends from the outer periphery of the main body toward the inner periphery but is spaced from the inner periphery; and
at least a diode provided in the engaging holes of the main body, wherein each said diode is peripherally provided with engaging ribs and has an end connected with wires.

2. The heat sink module of claim 1, wherein the main body has a shape selected from the group consisting of an arcuate shape, a horseshoe shape, and a semicircular shape.

3. The heat sink module of claim 1, wherein each said engaging hole has an inner surface formed with at least a vent slot in communication with the each said engaging hole.

4. The heat sink module of claim 2, wherein each said engaging hole has an inner surface formed with at least a vent slot in communication with the each said engaging hole.

5. The heat sink module of claim 1, wherein the total number of the first fins and the second fins in the fin array ranges from 40 to 47.

6. The heat sink module of claim 2, wherein the total number of the first fins and the second fins in the fin array ranges from 40 to 47.

7. The heat sink module of claim 3, wherein the total number of the first fins and the second fins in the fin array ranges from 40 to 47.

8. The heat sink module of claim 4, wherein the total number of the first fins and the second fins in the fin array ranges from 40 to 47.
